(19) United States
(12) Patent Application Publication
(10) Pub. No.: US 2005/0030827 A1
(43) Pub. Date: Feb. 10, 2005

(54) PMOS memory cell

(75) Inventors: Troy N. Gilliland, Newcastle, WA (US); Chad A. Lindhorst, Seattle, WA (US); Christopher J. Diorio, Shoreline, WA (US); Todd E. Humes, Shoreline, WA (US); Shailendra Srinivas, Seattle, WA (US)

Correspondence Address: David B. Ritchie, P.O. BOX 640640, San Jose, CA, 95164-0640, US

(73) Assignee: Impinj, Inc., a Delaware Corporation

(21) Appl. No.: 10/936,283

(22) Filed: Sep. 7, 2004

Related U.S. Application Data
(63) Continuation-in-part of application No. 10/245,183, filed on Sep. 16, 2002.

(51) Int. Cl. G11C 8/02

(52) U.S. Cl. 365/232

(57) ABSTRACT

A single-poly PMOS nonvolatile memory (NVM) cell and a method of programming, erasing and reading such a cell are implemented using a single-poly PMOS NVM cell which includes a floating gate injection transistor, a select switch, and a tunneling capacitor having one plate in common with the floating gate of the injection transistor. Methods of altering the number of electrons on the floating gate of the single-poly PMOS NVM cell are used which, with appropriate biasing of the components permit the power terminals of the cell to have appropriate voltages applied to thereby avoid stuck bits and induce hot electrons onto the floating gate of the NVM cell.

### RELATED APPLICATIONS

This application is a continuation in part of co-pending and commonly assigned U.S. patent application Ser. No. 10/245,183 filed Sep. 16, 2002 in the name of inventors Christopher J. Diorio, Troy N. Gilliland, Chad A. Lindhorst, Alberto Pesavento and Shailendra Srinivas and entitled “Method and Apparatus for Preventing Overtunneling in pFET-Based Nonvolatile Memory Cells” (Attorney Docket No. IMPJ-0022), which is hereby incorporated by reference as if set forth fully herein.

This application is also related to co-pending and commonly assigned U.S. patent application Ser. No. 10/______ filed on even date herewith in the name of inventors Christopher J. Diorio and Todd E. Humes and entitled “Method and Apparatus for Programming Single-Poly pFET-Based Nonvolatile Memory Cells” (Attorney Docket No. IMPJ-0029), which is hereby incorporated herein by reference as if set forth fully herein.

### FIELD OF THE INVENTION

The present invention relates generally to nonvolatile memory (NVM). More particularly, the present invention relates to p-channel metal oxide semiconductor field effect transistor-based (PMOS or pFET) NVM cells that avoid the occurrence of “stuck” bits.

### BACKGROUND OF THE INVENTION

Demand for embedded nonvolatile memory (NVM) in integrated circuits has grown steadily over the past decade. Desirable characteristics of embedded NVM include low cost, low power, high speed, and high reliability (data retention and program/erase cycling endurance). NVM may be embedded in various integrated circuit (IC) technologies such as, for example, the widely used Complementary Metal Oxide Semiconductor (CMOS) technology. Some embedded NVM in CMOS applications include, for example, storing: (1) chip serial numbers, (2) configuration information in ASICs (Application Specific Integrated Circuits), (3) product data, security information and/or serial numbers in radio frequency identification integrated circuits, (4) program code or data in embedded microcontrollers, and (5) analog trim information, and the like.

Traditional embedded EEPROMs (Electrically Erasable Programmable Read Only Memories) or Flash NVMs use NMOS (n-channel Metal Oxide Semiconductor) floating gate storage transistors (also referred to as nFET floating gate transistors). More recently, p-channel-based floating gate MOS (PMOS) memory cells have been used to implement embedded NVM. The PMOS-based memory cell exhibits various performance advantages over the more traditional NMOS-based memory cell. These performance advantages include: (1) increased program/erase cycle endurance (due to reduced oxide wear-out); (2) availability in logic CMOS processes (due to reduced memory leakage arising from more favorable oxide physics); (3) ability to easily store analog as well as digital values (due to availability of precise memory writes); and (4) smaller on-chip charge pumps (due to decreased charge pump current requirements).

FIG. 1 shows a cross-sectional view of a prior art PMOS memory cell 10 manufactured using a double-poly process (i.e., a fabrication process that forms a device having two layers of polysilicon). PMOS memory cell 10 includes a floating gate transistor 12 and a PMOS select transistor 14 formed in an n− well region 16 of a p− substrate 18. A first p+ diffusion region 20 serves as the drain of floating-gate transistor 12. A second p+ diffusion region 22 serves as the source of floating-gate transistor 12 and the drain of select transistor 14. A third p+ diffusion region 24 serves as the source of select transistor 14. A channel region 26 extends within n− well region 16 between first p+ diffusion region 20 and second p+ diffusion region 22. A polysilicon floating gate 28 is insulated from n− well region 16 by a thin oxide layer 30. A control gate 32 disposed over floating gate 28 is insulated from floating gate 28 by a second insulating layer 34.

Floating gate transistor 12 of memory cell 10 is a depletion mode device when programmed, i.e., when a sufficient number of electrons are stored on floating gate 28 to invert channel region 26 from n− type to p-type. Memory cell 10 is programmed using a process known as Impact-ionized Hot-Electron Injection (IHEI). IHEI occurs when charge carriers (in the case of a p-channel device, positively charged holes) are accelerated by an applied electric field formed across channel region 26. Collisions with electrons and lattice atoms in a depletion region formed in the vicinity of second p+ diffusion region 22 result in an excess of electrons, which can be pulled onto floating gate 28, if memory cell 10 is appropriately biased. To accelerate the charge carriers, a negative drain-to-source voltage (drain more negatively biased than source) is applied across first and second p+ diffusion regions 20 and 22. To form the depletion region a positive voltage is applied to control gate 32, which capacitively couples to floating gate 28 so that electrons are attracted to floating gate 28. Under these bias conditions, IHEI operates to create hot electrons by the impact of accelerated holes. The hot electrons are swept into (i.e., are injected) onto floating gate 28 by the relatively high voltage on the floating gate caused by the capacitively coupled control gate voltage

Memory cell 10 is erased by floating second p+ diffusion region 22, biasing first p+ diffusion region 20 to a relatively large positive voltage, and applying a relatively large negative voltage to control gate 32. Under these bias conditions a process known as Fowler-Nordheim (F-N) tunneling occurs, whereby electrons stored on floating gate 28 tunnel over an energy barrier created by the presence of thin oxide layer 30 into n− well region 16.

Memory cell 10 (as are the other devices described herein) is fabricated as a semiconductor device using a process technology having intrinsic voltage supply values, e.g., Vdd (high supply voltage) and Vss (low supply voltage—typically ground). In normal read operation, potentials of Vdd and Vss are applied to operate the cell. Values outside this range (typically obtained with charge pumps) may be required to write to such cells. Memory cell 10 is therefore read by applying a voltage less than the programming voltage, i.e., Vdd<V_{T(prog)}, across control gate 32 and first p+ diffusion region 20, biasing the gate 36 of select transistor 14 so that select transistor 14 is on, and connecting n− well region 16, second p+ diffusion region 22 and control gate 32 to a supply voltage, Vdd (e.g., about 3.3 volts for devices fabricated in a 0.35 micron process technology—different process technologies have different intrinsic supply values). Under these bias conditions, selected floating gate transistor 12 conducts a channel current if memory cell 10 is programmed. Otherwise, it does not.

The motivation behind using control gate 32 in memory cell 10 relates to its use in preventing “stuck bits” from occurring in memory structures using PMOS NVM cells. A stuck bit arises when the channel in floating gate transistor 12 is insufficiently formed to support IHEI. Such a condition may arise due to an over-erasure of memory cell 10 or post fabrication starting charge present on floating gate 28. Control gate 32 helps to turn floating gate transistor 12 on, thereby avoiding the stuck bit problem.

Whereas the double poly fabrication process described above is beneficial in that it provides a control gate that can be used to avoid stuck bits, the process requires additional processing steps beyond that which are used in conventional logic CMOS (Complementary Metal Oxide Semiconductor) process technologies. Accordingly, using a double poly process for embedded NVM is relatively costly and, therefore, avoiding it would be desirable in many applications.

To reduce the costs and added complexities of embedding NMOS NVM in ICs, efforts have been made to design an NVM that can be integrated with conventional logic CMOS process technology, without having to introduce additional processing steps. FIG. 2 shows a prior art single-poly PMOS NVM 40 disclosed in U.S. Pat. No. 5,761,121. As shown in FIG. 2, PMOS NVM 40 includes a storage transistor 42, having a drain 44, a source 46 and a floating gate 48, and a separate control gate structure 50, having a p− doped control gate implant 52. The use of a single-poly process to manufacture NVM 40 is beneficial in that it is PMOS-based and avoids application of a double-poly process. Unfortunately, however, the single-poly process used is complicated somewhat by the fact that it requires special processing steps (e.g., masking, implantation, cleaning, etc.) and handling to form the separate control gate structure 50. These additional process steps result in higher manufacturing costs and potentially lower yields.

Therefore, there is a need for an improved memory cell that does not suffer from the drawbacks associated with devices manufactured using a double-poly process or the drawbacks associated with a single-poly implementation requiring special processing steps to form a control gate structure.

### SUMMARY OF THE INVENTION

A single-poly PMOS nonvolatile memory (NVM) cell and a method of programming, erasing and reading such a cell are implemented using a single-poly PMOS NVM cell which includes a floating gate injection transistor, a select switch, and a tunneling capacitor having one plate in common with the floating gate of the injection transistor. Methods of altering the number of electrons on the floating gate of the single-poly PMOS NVM cell are used which, with appropriate biasing of the components permit the power terminals of the cell to have appropriate voltages applied and thereby avoid stuck bits and induce hot electrons onto the floating gate of the NVM cell.

Other aspects of the inventions are described and claimed below, and a further understanding of the nature and advantages of the inventions may be realized by reference to the remaining portions of the specification and the attached drawings

### BRIEF DESCRIPTION OF THE DRAWINGS

The accompanying drawings, which are incorporated into and constitute a part of this specification, illustrate one or more embodiments of the present invention and, together with the detailed description, serve to explain the principles and implementations of the invention.

In the drawings:

FIG. 1 is an elevational cross-sectional view of a prior art PMOS memory cell manufactured using a double-poly process.

FIG. 2 is an elevational cross-sectional view of a prior art single-poly PMOS memory cell having a control gate structure.

FIG. 3A is an electrical schematic diagram of a PMOS memory cell in accordance with an embodiment of the present invention.

FIG. 3B is a top layout view of the PMOS memory cell of FIG. 3A in accordance with an embodiment of the present invention.

FIG. 3C is an elevational cross-sectional diagram of the PMOS memory cell of FIGS. 3A and 3B, taken along line 3C-3C of FIG. 3B in accordance with an embodiment of the present invention.

FIG. 4A is an electrical schematic diagram of a multi-stage positive voltage charge pump circuit having an output that may be used to pulse selected transistor source terminals to a voltage greater than the nominal supply voltage in accordance with an embodiment of the present invention.

FIG. 4B is an electrical schematic diagram of a single-stage negative voltage charge pump having an output that may be used to pulse an injection transistor drain terminal to a voltage below ground potential in accordance with an embodiment of the present invention.

FIGS. 5A, 5B and 5D are electrical schematic diagrams illustrating various embodiments of memory circuits including overtunneling prevention control circuits in accordance with various embodiments of the present invention. FIG. 5C is a timing diagram corresponding to the circuit of FIG. 5B.

FIG. 6 is an electrical schematic diagram of a 2×2 array of memory cells using PMOS memory cells like the one shown in FIGS. 3A, 3B and 3C in accordance with an embodiment of the present invention.

FIG. 7A is an electrical schematic diagram of the PMOS memory cell shown in FIGS. 3A, 3B and 3C which has been modified so that it includes a control capacitor in accordance with an embodiment of the present invention.

FIG. 7B is an electrical schematic diagram of a 2×2 array of memory cells using PMOS memory cells like the one shown in FIG. 7A in accordance with an embodiment of the present invention.

FIG. 7C is a top layout view of the PMOS memory cell of FIG. 7A in accordance with an embodiment of the present invention.

FIG. 7D is an elevational cross-sectional diagram of the PMOS memory cell of FIGS. 7A and 7C, taken along line 7D-7D of FIG. 7C in accordance with an embodiment of the present invention.

FIG. 7E is a top layout view of an alternate embodiment of the PMOS memory cell of FIG. 7A in accordance with the present invention.

FIG. 7F is an elevational cross-sectional diagram of the PMOS memory cell of FIG. 7E, taken along line 7F-7F of FIG. 7E in accordance with an embodiment of the present invention.

FIG. 7G is a top layout view of another alternate embodiment of the PMOS memory cell of FIG. 7A in accordance with the present invention.

FIG. 7H is an elevational cross-sectional diagram of the PMOS memory cell of FIGS. 7G, taken along line 7H-7H of FIG. 7G in accordance with an embodiment of the present invention.

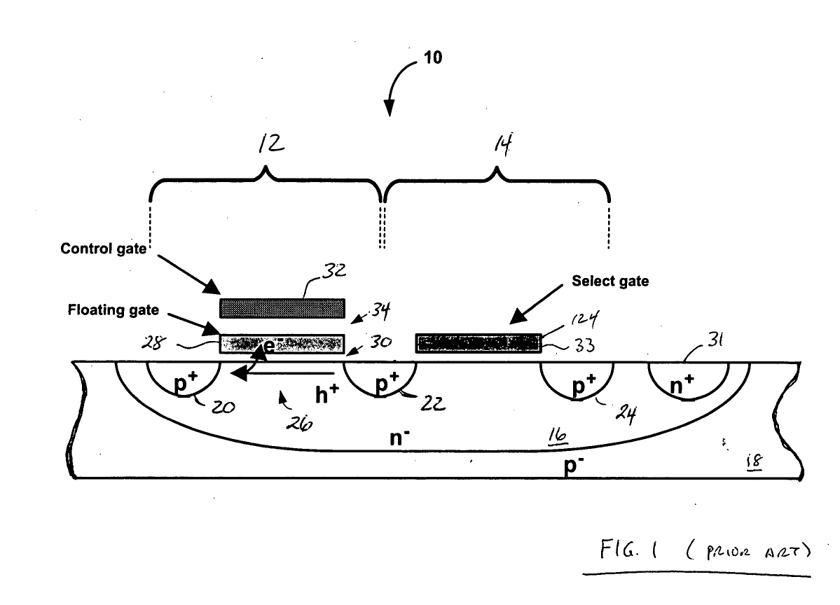

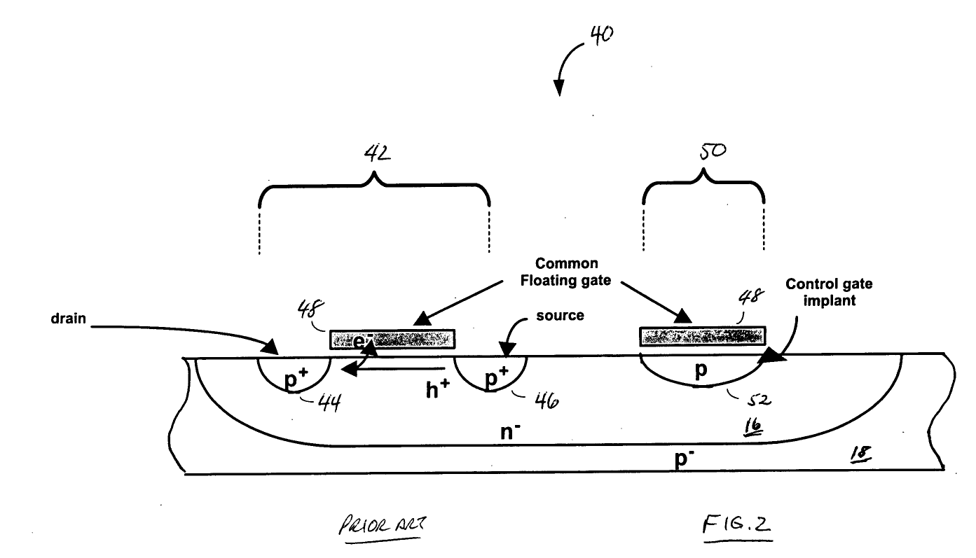

### DETAILED DESCRIPTION

Embodiments of the present invention described herein are of PMOS NVM cells and methods of preventing the occurrence of stuck bits in such PMOS NVM cells. Those of ordinary skill in the art will realize that the following detailed description of the present invention is illustrative only and is not intended to be in any way limiting. Other embodiments of the present invention will readily suggest themselves to such skilled persons having the benefit of this disclosure. Reference will now be made in detail to implementations of the present invention as illustrated in the accompanying drawings. Where appropriate, the same reference indicators will be used throughout the drawings and the following detailed description to refer to the same or similar parts.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

As used herein, the symbol n+ indicates an n-doped semiconductor material typically having a doping level of n-type dopants on the order of 10²¹ atoms per cubic centimeter. The symbol n− indicates an n-doped semiconductor material typically having a doping level on the order of 10¹⁷ atoms per cubic centimeter. The symbol p+ indicates a p-doped semiconductor material typically having a doping level of p-type dopants on the order of 10²¹ atoms per cubic centimeter. The symbol p− indicates a p-doped semiconductor material typically having a doping level on the order of 10¹⁷ atoms per cubic centimeter for p− doped wells and on the order of 10¹⁵ atoms per cubic centimeter for p− substrate material. Those of ordinary skill in the art will now realize that the devices described herein may be formed on a conventional semiconductor substrate or they may as easily be formed as a thin film transistor (TFT) above the substrate, or in silicon on an insulator (SOI) such as glass (SOG), sapphire (SOS), or other substrates as known to those of ordinary skill in the art. Such persons of ordinary skill in the art will now also realize that a range of doping concentrations around those described above will also work. Essentially, any process capable of forming pFETs and nFETs will work. Doped regions may be diffusions or they may be implanted. When it is said that something is doped at approximately the same level as something else, the doping levels are within a factor often of each other, e.g., 10¹⁶ is within a factor often of 10¹⁵ and 10¹⁷.

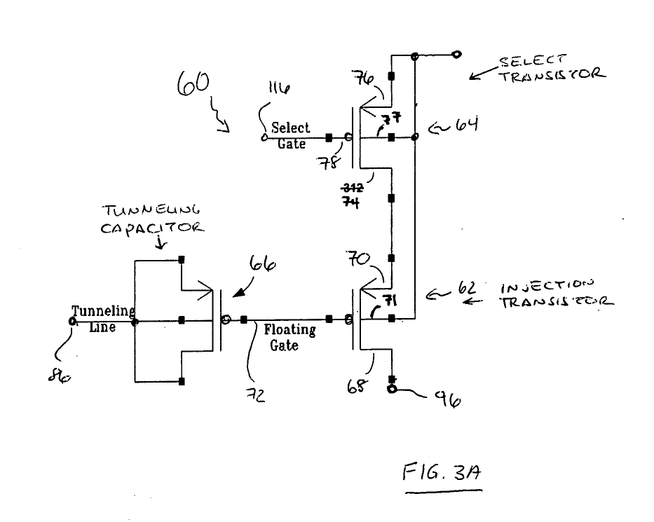

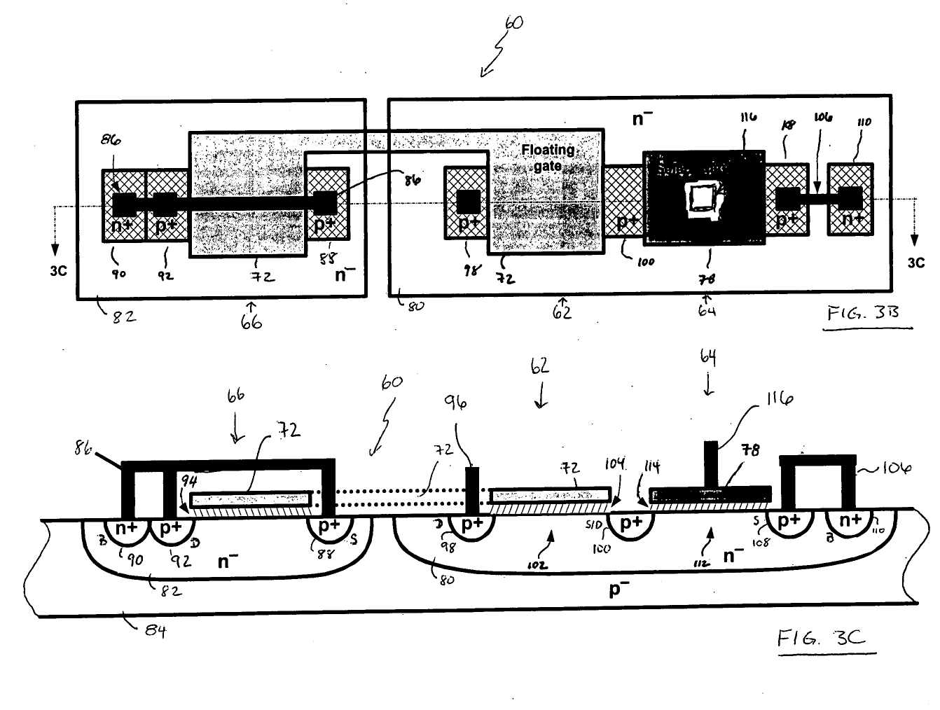

Turning now to FIGS. 3A, 3B and 3C, there is shown in FIG. 3A an electrical schematic diagram of a PMOS NVM cell 60 in accordance with an embodiment of the present invention. As described in more detail below, PMOS NVM cell 60 includes only a single polysilicon layer and a corresponding single gate oxide layer (typically about 70 angstroms thick in a 3.3 volt device—less thick in lower voltage devices) and does not include or require a control gate or control gate structure. As shown in FIG. 3A, PMOS NVM cell 60 comprises a p-type injection transistor 62, a p-type select transistor 64, and a tunneling capacitor 66 (formed in accordance with this embodiment of a shorted p-type transistor). Injection transistor 62 has a drain 68, which may be coupled to a column line in a memory array structure as described in more detail below, a source 70, a well 71 and a floating gate 72. Select transistor 64 has a drain 74, which is coupled to source 70 of injection transistor 62, a source 76, which may be coupled to a bit line in a memory array structure as described in more detail below, a well 77 and a select gate 78. In the FIG. 3A embodiment, wells 71 and 77 and source 76 are coupled together. Tunneling capacitor 66 has a first plate formed by the shorting together of drain, source and body terminals of a PMOS transistor, and a second plate formed from a portion of floating gate 72. Whereas tunneling capacitor 66 is shown as being formed from a PMOS transistor having its drain, source and body shorted together to form the second plate of the tunneling capacitor, those skilled in the art will now readily understand that other ways of implementing the tunneling capacitor may be employed. For example, one or two of the source, drain and body contacts may be left floating, while still implementing a MOS capacitor structure. Other known tunneling structures may be used as well.

FIGS. 3B and 3C are top layout and elevational cross-sectional diagrams of the PMOS NVM 60 shown in FIG. 3A. FIGS. 3B and 3C show that injection transistor 62 and select transistor 64 are formed in a common first n− well 80 and that tunneling capacitor 66 is formed in a second n− well 82. Both first n− well 80 and second n− well 82 are formed in a p− substrate 84 (FIG. 3C). A tunneling line 86 is coupled to source (p+), body (n+) and drain (p+) contact diffusions (88, 90 and 92, respectively), to provide a first terminal for tunneling capacitor 66. An insulating layer 94 (FIG. 3C) insulates tunneling line 86 of tunneling capacitor 66 from the second plate of tunneling capacitor 66, which, as described above and shown in FIG. 3B, is formed from a portion of floating gate 72. An injection transistor drain terminal 96 is coupled to a p+ drain diffusion 98, which embodies the drain 68 of injection transistor 62. As explained below, injection transistor drain terminal 96 may be coupled to a column line in a memory array of PMOS NVM cells 60. Although not required as being common, a common p+ source/drain diffusion 100 embodies the source 70 of injection transistor 62 and the drain 74 of select transistor 64. Floating gate 72 overlies an injection transistor channel region 102 extending between p+ drain diffusion 98 and p+ source/drain diffusion 100. An insulating layer 104, which may be part of insulating layer 94, and may be formed of a grown or deposited gate oxide, insulates floating gate 72 from injection transistor channel region 102. A select transistor source terminal 106 is coupled to a p+ source diffusion 108, which embodies the source 76 of select transistor 64. An n+ well contact diffusion 110 for making contact to n− well 80 is coupled to select transistor source terminal 106. As explained below, select transistor source terminal 106 may be coupled to a bit line in a memory array of PMOS NVM cells 60. A select transistor channel region 112 extends between source/drain diffusion 100 and source diffusion 108. An insulating layer 114, which may also be part of insulating layer 94 and/or insulating layer 104, and may be formed of grown or deposited gate oxide, insulates select gate 78 of select transistor 64 from select transistor channel region 112. A select gate terminal 116 is coupled to select gate 78. Select gate 78 and floating gate 72, while being electrically physically and electrically separate, are etched or formed from a single polysilicon layer.

PMOS NVM cell 60 is programmed as follows. Tunneling line 86 is biased to a first potential and select gate terminal 116 is biased to a second potential. In accordance with one embodiment of the invention, these first and second potentials are the same and are at ground potential. With tunneling line 86 and select gate terminal 116 biased as just described, select transistor source terminal 106 may be pulsed above the normal supply voltage rail of Vdd (e.g., about 3.3 volts nominal). In accordance with one embodiment of the invention, this select transistor pulse voltage V_{PULSE1} is approximately (2×Vdd)−Vtp, where Vtp is the threshold voltage of PMOS select transistor 64 (e.g., approximately 0.8 volts).

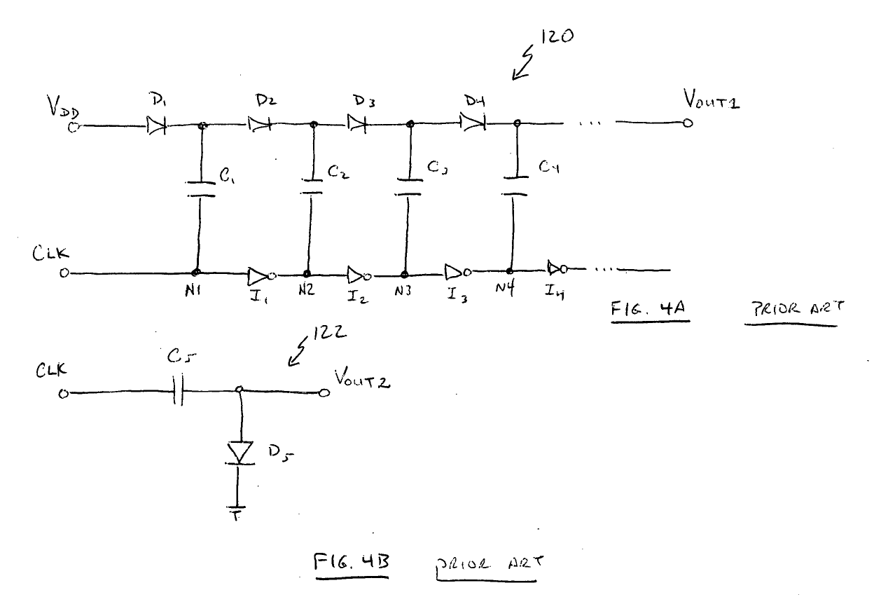

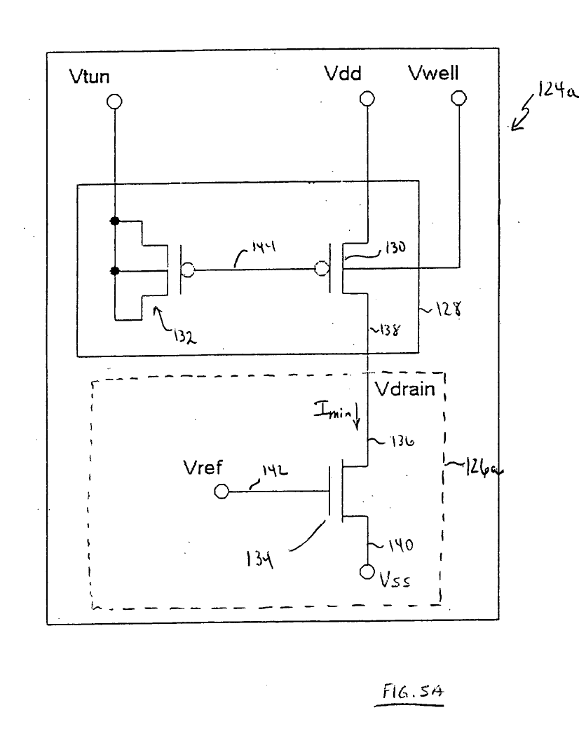

FIG. 4A is an electrical schematic diagram of an example of a multi-stage positive charge pump circuit 120 that may be used to generate an output voltage, V_{OUT1}, which may, in turn, be used as a source for generating V_{PULSE1}. In accordance with this example of a charge pump the first stage takes Vdd through diode D1 (and the rest of the odd stages (i.e., 3, 5, . . . ) where it experiences a voltage drop and uses that voltage to charge capacitor C1 (and the other odd capacitors) while the CLK (clock) signal is low. When CLK is high the charge in the odd capacitors moves to the next stage and the even stages charge up. In this way V_{OUT1} becomes equal to Vdd less the diode drop multiplied by the number of stages employed. Those of ordinary skill in the art will now readily appreciate that charge pump 120 is only exemplary and that other types of single-stage and multi-stage voltage boosting circuits may be used to obtain essentially any desired voltage.

xIf PMOS NVM 60 is disposed in a memory array, as described below, V_{PULSE1} would be applied provided by the appropriate bit line coupled to select transistor source terminal 106. While tunneling line 86 and select gate terminal 116 are biased and V_{PULSE1} is being applied to select transistor source terminal 106, injection transistor drain terminal 96 may be alternatively (or additionally) pulsed below ground potential. In accordance with an embodiment of the present invention, this injection transistor pulse voltage V_{PULSE2} is approximately −Vdd−Vtp).

FIG. 4B is an electrical schematic diagram of an example of a single-stage negative charge pump 122 which may be used to generate an output voltage, V_{OUT2}, which can be used as a source for generating V_{PULSE2}. In accordance with this example charge pump, an oscillating clock signal, CLK, with an amplitude of Vdd is applied to a first plate of capacitor C5. The other plate is coupled to ground through diode D5. When the second plate is mode than a diode threshold voltage above ground, diode D5 conducts to a voltage of V_{ON}. When it is negative, diode D5 does not conduct, thus the V_{OUT2} node is held at roughly −Vdd−V_{ON}). Those skilled in the art will readily now understand that charge pump 122 is only exemplary and that other types of voltage lowering circuits may be used.

If PMOS NVM 60 is disposed in a memory array, as described below, V_{PULSE2} would be provided by the appropriate column line coupled to injection transistor drain terminal 96. Under the foregoing bias conditions, a sufficient channel current flows through select transistor 64 and injection transistor 62 to cause IHEI and to occur, thereby adding electrons to floating gate 72.

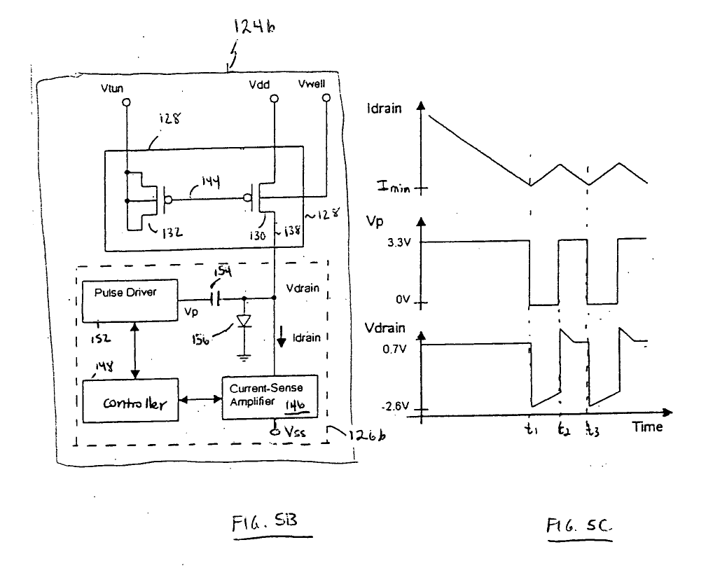

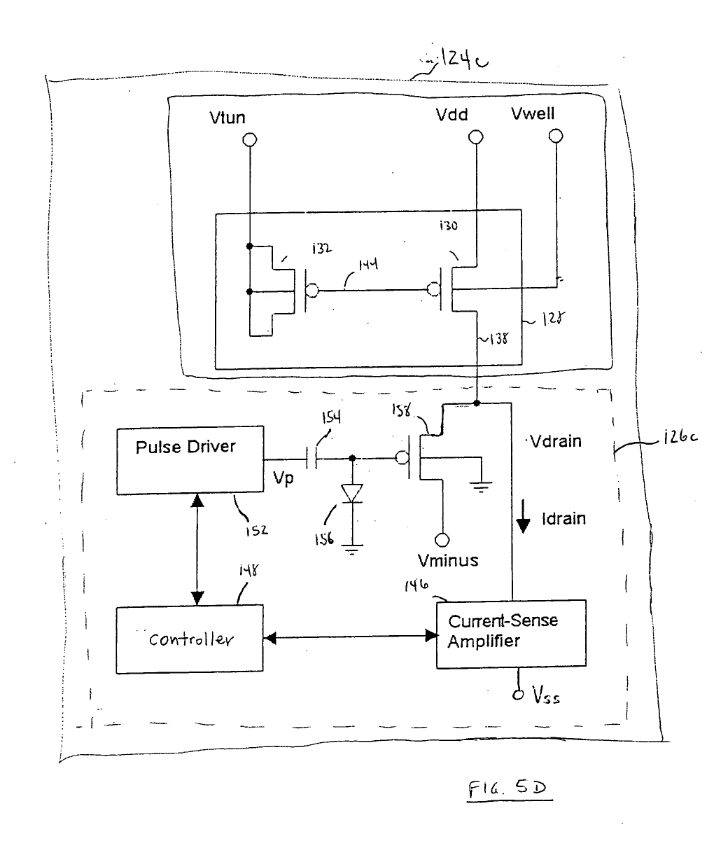

Pulsing select transistor source terminal 106 above the voltage supply rail Vdd, and/or pulsing injection transistor drain terminal 96 below ground potential ensures that injection transistor 62 turns on and conducts, even if the bit associated with the selected memory cell is stuck, as may be the case, for example, if the memory cell had been previously over-erased. When pulsing (or simply applying) a voltage above Vdd to the source of the injection transistor while simultaneously pulsing (or simply applying) a voltage below Vss (ground) to the drain of the injection transistor the programming occurs faster and prevents stuck bits. Nevertheless, additional measures may be taken to limit the tunneling voltage to thereby further avoid the generation of stuck bits. According to one embodiment, the channel current is monitored and prevented from dropping below a predetermined threshold minimum channel current using an overtunneling prevention control circuit (OPCC). The OPCC injects charge carriers onto the floating gate using IHEI so that overtunneling is avoided. Exemplary OPCCs, which may be used or modified and used to prevent overtunneling in the PMOS memory cells disclosed in the present application, are disclosed in co-pending and commonly assigned U.S. patent application Ser. No. 10/245,183 filed Jul. 28, 2003 in the names of inventors Christopher J. Diorio, Troy N. Gilliland, Chad A. Lindhorst, Alberto Pesavento and Shailendra Srinivas and entitled “Method and Apparatus for Preventing Overtunneling in pFET-Based Nonvolatile Memory Cells.” Some such OPCCs are illustrated in FIGS. 5A, 5B, 5C and 5D hereof.

FIG. 5A is an electrical schematic diagram illustrating a memory circuit 124a including an OPCC 126a for preventing overtunneling in a pFET-based memory cell 128. Memory circuit 124a comprises a memory cell 128 having an injection transistor 130 and a tunneling capacitor 132. OPCC 126a includes an nFET (i.e. an n-channel MOSFET or NMOS transistor) overtunneling prevention transistor 134 having a drain 136 coupled to the drain 138 of injection transistor 130, a source 140 coupled to a negative supply voltage Vss, and a gate 142 coupled to a reference voltage Vref. Memory circuit 124a in FIG. 5A operates as follows. Assume the voltage on the floating gate 144 is low, and it is desired to tunnel it up. To tunnel up floating gate 144 a tunnel voltage Vtun of about (Vfg+10V), where Vfg is the floating gate voltage and 10V is typical for a 0.35 μm CMOS process with 75 Å oxides, is applied to the tunneling capacitor 132. Vtun causes electrons to tunnel from floating gate 144, through the tunneling capacitor's dielectric (i.e., the gate oxide, if tunneling capacitor is formed from a pFET or an nFET), to Vtun, thereby raising Vfg. To prevent overtunneling, a reference voltage Vref is applied to the gate of overtunneling prevention transistor 134. Overtunneling prevention transistor 134 operates by sinking a small current Imin (e.g. ˜250 nA) from injection transistor 130. As long as injection transistor 130 is able to source more current than overtunneling prevention transistor 134 sinks, Vdrain remains high, and injection transistor 130 will not inject electrons onto floating gate 144. When, however, Vfg rises so high that injection transistor 130 can no longer source Imin, Vdrain will fall, causing injection transistor 130 to begin injecting electrons onto floating gate 144. Eventually, Vdrain will stabilize at a voltage where the IHEI gate current is equal and opposite to the tunneling gate current. Hence, overtunneling prevention transistor 134 prevents injection transistor 130 from turning off by injecting electrons back onto floating gate 144, thereby forcing the channel current of injection transistor 130 to maintain a value equal to Imin.

In 0.35 μm and smaller CMOS logic processes, a voltage of not more than about 12V can be applied to the body of tunneling capacitor 132, without risking body-to-substrate breakdown. Because a voltage of approximately 10V is needed across the gate oxide of tunneling capacitors 132 to cause appreciable electron tunneling, Vfg must be roughly (12V−10V)=2V. To obtain channel currents in the range of 10 nA to 10 μA, Vdd should then be about 3.3V. To obtain reasonable IHEI in injection transistor 130, Vdrain should be about −2V, meaning Vss should be about −2.5V. Unfortunately, most modern n-well CMOS processes do not offer nFETs that operate with a Vss of more than a few hundred millivolts below ground, because the nFET's substrate-to-source and substrate-to-drain p-n junctions become forward biased. If such limitations are encountered, other approaches may be used. One alternative approach is to use a deep n-well or a dual-well process and fabricate an overtunneling prevention transistor, like transistor 134 shown in FIG. 5A, in a p-well that can be biased about 2.5V below ground. Another alternative approach is to provide an OPCC to emulate the functions of the overtunneling prevention transistor 134 without having to resort to additional processing steps necessary to create a p-well operating below ground. FIG. 5B shows an example of the latter alternative.

Referring now to FIG. 5B, an electrical schematic diagram illustrates a memory circuit 124b including an OPCC 126b for preventing overtunneling in a pFET-based memory cell. Memory circuit 126b comprises a memory cell 128 having an injection transistor 130 and a tunneling capacitor 132, which may be formed from a pFET transistor as shown. The drain 138 of injection transistor 130 is coupled to OPCC 126b, which, in turn, comprises a current sense amplifier 146, a controller 148 coupled to current sense amplifier 146, a pulse driver 152 coupled to controller 148, a capacitor 154 coupled between pulse driver 152 and drain 138 of injection transistor 130, and a diode 156 coupled between drain 138 of injection transistor 130 and Vss (which may be ground).

Memory circuit 124b in FIG. 5B operates as follows. During tunneling (or in-between tunneling pulses), the current sense amplifier 146 monitors the drain current Idrain of injection transistor 130. Tunneling causes Idrain to gradually decrease, as shown in the timing diagram provided in FIG. 5C. Current sense amplifier 146 is configured to trigger when Idrain decreases to a value of Imin. When current sense amplifier 146 triggers, controller 148 instructs pulse driver 152 to pull Vp from Vdd (nominally 3.3V) down to Vss (which may be ground). This is indicated in FIG. 5C as occurring at time t1. Capacitor 154 then pulls the drain voltage Vdrain of injection transistor 130 from 0.7V (the “on” voltage of diode 156) to −2.6V, causing electron injection to commence in injection transistor 130, and thereby causing Idrain to increase. After a short period of time, at time t2 (FIG. 5C) controller 148 instructs pulse driver 152 to pull Vp from ground back up to Vdd, and waits for current sense amplifier 146 to trigger again. In this manner, OPCC 126b pulses Vdrain as needed to ensure that injection transistor 130 is not over-tunneled into an “off” state. Note that, although a “current sense” amplifier is employed to determine when Vdrain must be pulsed low to avoid overtunneling, other sensing or monitoring devices and circuits may be used. For example, the cell current may be supplied to any one of many possible current-to-voltage circuit elements (e.g. resistor, diode, current source, etc.) so that a voltage is measured and/or monitored, rather than transistor 130's drain current itself.

FIG. 5D is an electrical schematic diagram illustrating the memory circuit 124b of FIG. 5B as modified to take advantage of an available negative voltage source Vminus, which would nominally be about −3.3V in a 0.35 μm CMOS process. Modified memory circuit 124c of FIG. SD comprises essentially the same elements as in memory circuit 124b of FIG. 5B, but also includes a source-follower-connected pFET 158 configured to operate as a negative-voltage switch. In one embodiment, Vminus may be provided by an off-chip voltage source. In an alternative embodiment, Vminus may be generated on the same semiconductor chip shared by memory cell 128 by using, for example, a negative-voltage charge pump. Source-follower-connected transistor 158 forms a negative-voltage switch as follows. When pulse driver 152 pulls Vp from Vdd (e.g. 3.3V) to ground and the gate of source-follower-connected transistor 158 is pulled to about −2.6V, the source of source-follower-connected transistor 158, and with it Vdrain, gets pulled down to about −2V.

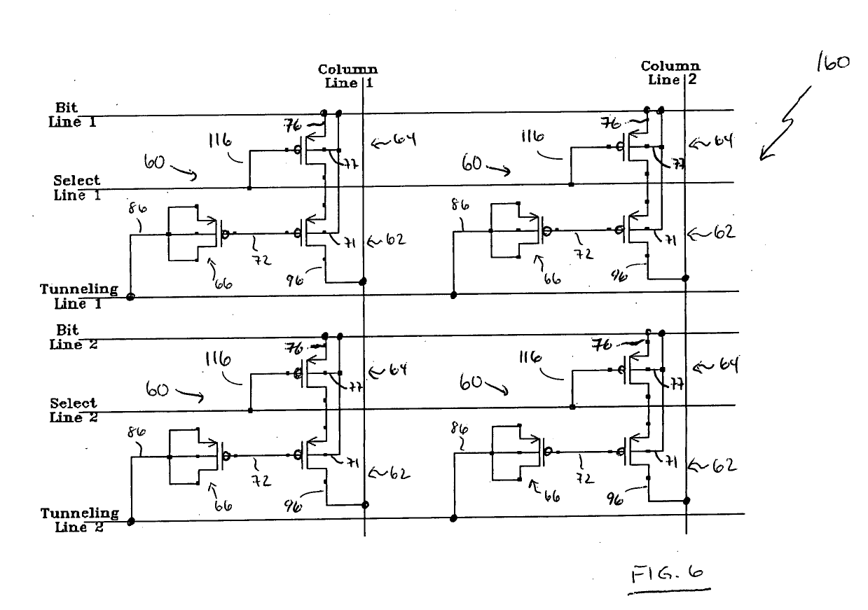

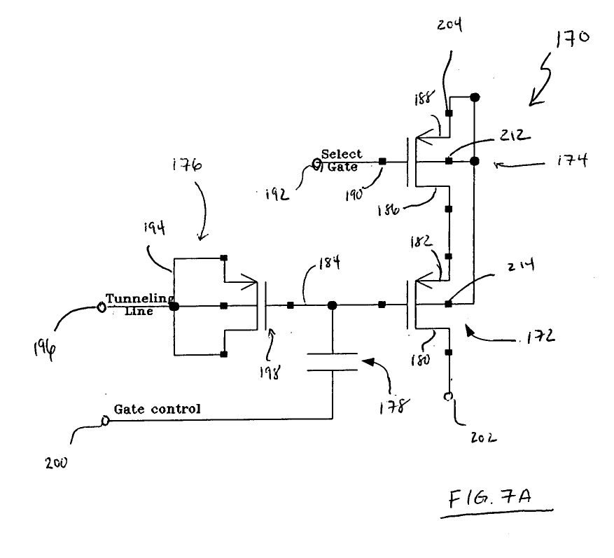

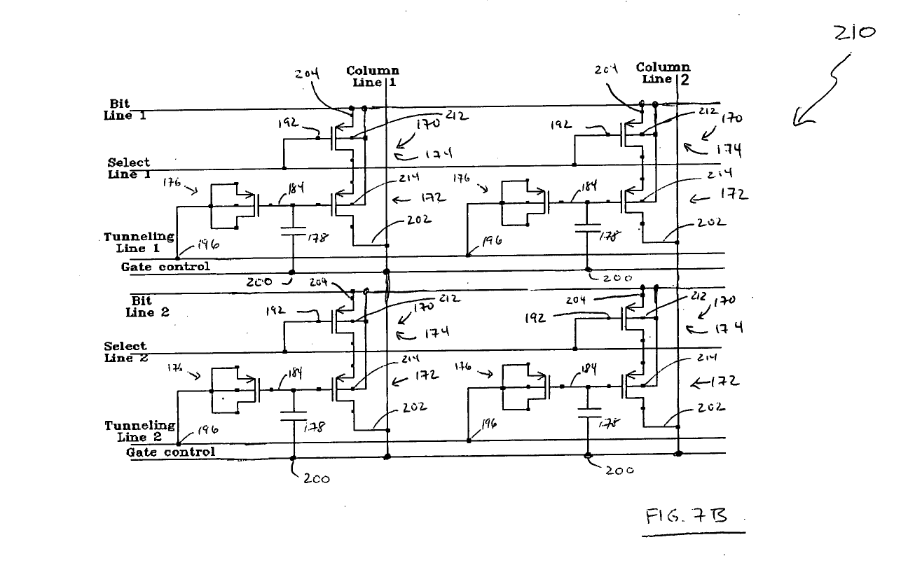

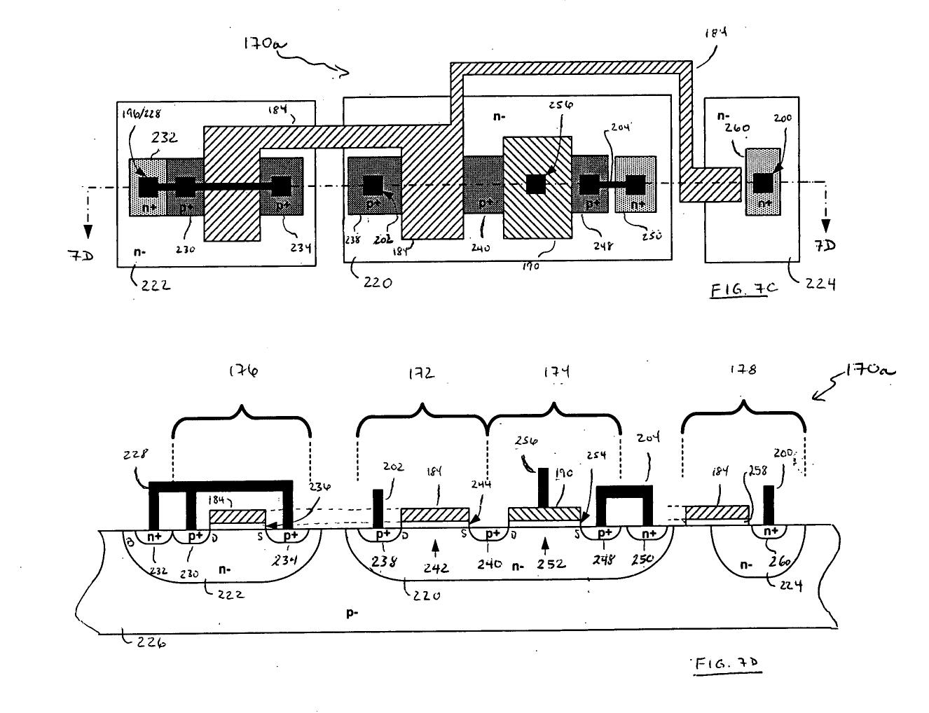

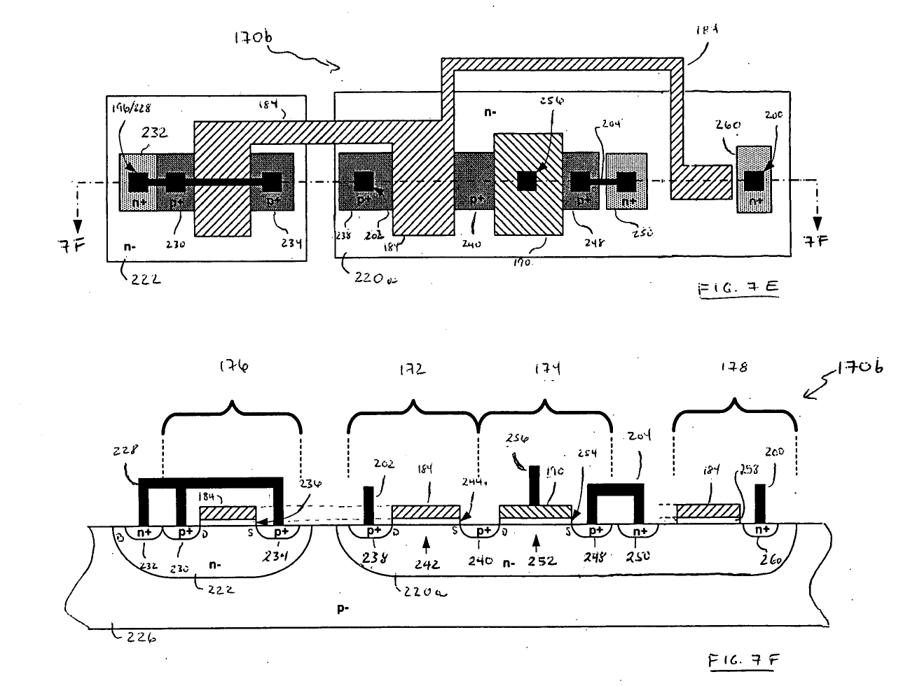

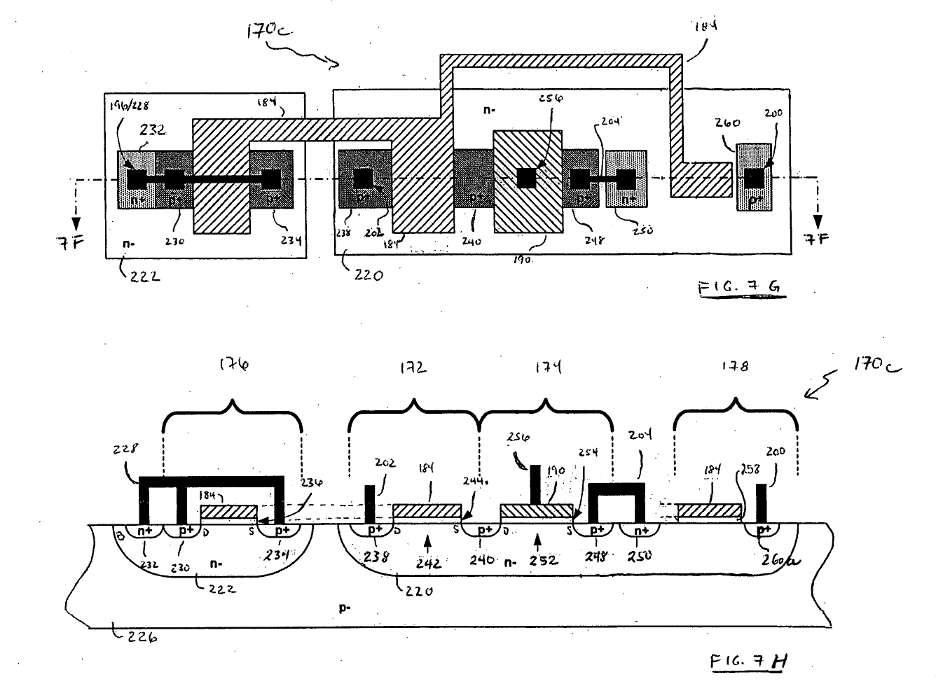

The OPCC circuits illustrated in FIGS. 5A, 5B and 5D may be incorporated in the array embodiments of FIGS. 6 and 7B (although it would be redundant in the FIG. 7B case) by tying them to the column lines—thus only one OPCC would be required for each column and it is then scanned to check one row at a time.

Turning back to FIGS. 3A, 3B and 3C, to erase PMOS NVM cell 60, select transistor source terminal 106 is biased to a third potential and injection transistor drain terminal 96 is biased to a fourth potential. According to one embodiment of the invention, the third and fourth potentials are the same and are at ground potential. Under these bias conditions, a sufficiently high voltage (e.g., nine volts) is applied to tunneling line 86 to cause a sufficiently strong electric field in the vicinity of the floating gate so that electrons are tunneled off of floating gate 72 by F-N tunneling. To read PMOS NVM cell 60, select transistor source terminal 106 is biased to a fifth potential (to Vdd potential in one embodiment of the invention) and the current flowing through injection transistor drain terminal 96 (or connected column line if the memory cell is disposed in a memory array) is converted to a logic value. The logic value depends upon the amount of charge (electrons) stored on floating gate 72, i.e., whether memory cell 60 is programmed or erased.

FIG. 6 is an electrical schematic diagram illustrating how a plurality of PMOS NVM cells 60 (FIG. 3A) may be configured to form a memory array 160, according to an embodiment of the present invention. Whereas only a 2×2 array of cells is shown, those of ordinary skill in the art will now readily understand that the array can be of any m×n size, where m and n are positive integers. As shown in FIG. 6, the injection transistor drain terminal 96 of each memory cell 60 in a given column of array 160 is coupled to a common column line; the source terminal 76 and well terminal 77 of each select transistor 64 (and the well terminal 71 of injection transistor 62) in a given row of array 160 is coupled to a common bit line; the select gate terminal 116 of each select transistor 64 in a given row is coupled to a common select line; and the tunneling line 86 of each tunneling capacitor in a given row of the array 160 is coupled to a common tunneling line.

Turning now to FIGS. 7A, 7B, 7C and 7D, there is shown in FIG. 7A a schematic diagram of a PMOS NVM cell 170a in accordance with an embodiment of the present invention. PMOS NVM cell 170a includes only a single polysilicon layer and does not include or require a control gate or control gate structure. As shown in FIG. 7A, PMOS NVM cell 170a comprises a p-type injection transistor 172, a p-type select transistor 174, a tunneling capacitor 176 formed from a shorted (drain-source-body) p-type transistor, and a control capacitor 178. Injection transistor 172 has a drain 180, which may be coupled to a column line in a memory array structure as described in more detail below, a source 182, and a floating gate 184. Select transistor 174 has a drain 186, which is coupled to source 182 of injection transistor 172, a source 188, which may be coupled to a bit line in a memory array structure as described in more detail below, and a select gate 190 with a select gate terminal 192. Tunneling capacitor 176 has a first plate 194 formed by the shorting together of drain, source and body terminals of a PMOS transistor (its terminal is denoted 196), and a second plate 198 formed from a portion of floating gate 184. Whereas tunneling capacitor 176 is shown as being formed from a PMOS transistor having its drain, source and body shorted together to form the second plate of the tunneling capacitor, those of ordinary skill in the art will now readily understand that other ways of implementing the tunneling capacitor 176 may be employed. For example, one or two of the source, drain and body contacts may be left floating, while still implementing a MOS capacitor structure. Alternatively, other known tunneling structures may be used. Control capacitor 178 is coupled to floating gate 184 and has a control capacitor terminal 200. The terminal associated with drain 180 of injection transistor 172 is denoted 202. The terminal associated with source 188 of select transistor 174 is denoted 204 and is also coupled as shown to the wells of select transistor 174 and injection transistor 172.

In the circuit of FIG. 7A, the control capacitor 178 is used to force the floating gate voltage to a level so that current flows through the device. It is, in essence, another mechanism for clearing or preventing stuck bits.

FIG. 7B is an electrical schematic diagram illustrating how a plurality of PMOS NVM cells 170a may be configured to form a memory array 210, according to an embodiment of the present invention. Whereas only a 2×2 array of cells is shown, those of ordinary skill in the art will now readily understand that the array can be of any m×n size, where m and n are positive integers. As shown in FIG. 7B, the injection transistor drain terminal 202 of each memory cell 170a in a given column of array 210 is coupled to a common column line; the source terminal 204 and well terminal 212 of each select transistor 174 (and the well terminal 214 of injection transistor 172) in a given row of array 210 is coupled to a common bit line; the select gate terminal 192 of each select transistor 174 in a given row is coupled to a common select line (select line 1, select line 2); and the tunneling line terminal 196 of each tunneling capacitor in a given row of the array 210 is coupled to a common tunneling line (tunneling line 1, tunneling line 2). Finally, the gate control terminals 200 coupled to control capacitors 178 in a given row of array 210 are coupled to a common gate control line (gate control) and to the associated column lines (column line 1, column line 2) so that assertion of the gate control signal. Asserting the control voltage couples the floating gate by an offset (determined by coupling ratio and control voltage magnitude) that aids reading, programming and erasing by always ensuring current is flowing through the injection device. In an alternative embodiment, one or more of control capacitor terminals may be biased by a separate voltage source.

FIGS. 7C and 7D are, respectively, top layout and elevational cross-sectional diagrams of the PMOS NVM 170a of FIG. 7A. FIG. 7C shows that injection transistor 172 and select transistor 174 are formed in a common n− well 220 and that tunneling capacitor 176 and control capacitor 178 are formed, respectively, in a second n− well 222 and a third n− well 224. First n− well 220, second n− well 222, and third n− well 224 are all formed in a p− substrate 226. A tunneling line 228 is coupled to source (p+), body (n+) and drain (p+) contact diffusions (230, 232 and 234, respectively), to provide a first terminal 194 for tunneling capacitor 176. An insulating layer 236 (which may be formed of a grown or deposited oxide or similar insulating material) insulates tunneling line 228 of tunneling capacitor 176 from the second plate 198 of tunneling capacitor 176, which, as described above and shown in FIG. 7C, is formed from a portion of floating gate 184. An injection transistor drain terminal 202 is coupled to a p+ drain diffusion 238, which embodies the drain 180 of injection transistor 172. As explained below, injection transistor drain terminal 202 may be coupled to a column line in a memory array of PMOS NVMs cells 170a. Although not required to be common, a common source/drain p+ diffusion 240 embodies the source 182 of injection transistor 172 and the drain 186 of select transistor 174. Floating gate 184 overlies an injection transistor channel region 242 extending between drain diffusion 238 and source/drain diffusion 240. An insulating layer 244, which may be of the same material as insulating layer 236, insulates floating gate 184 from injection transistor channel region 242. A select transistor source terminal 204 is coupled to a p+ source diffusion 248, which embodies the source 188 of select transistor 174. An n+ well contact diffusion 250 for making contact to n− well 220 is coupled to select transistor source terminal 204. As explained below, select transistor source terminal 204 may be coupled to a bit line (bitline 1, bitline 2) in a memory array of PMOS NVM cells 170a. A select transistor channel region 252 extends between source/drain diffusion 240 and source diffusion 248. An insulating layer 254, which may be of the same material as insulating layer 236 and/or 244, insulates select gate 190 of select transistor 174 from select transistor channel region 252. A select gate terminal 256 is coupled to select gate 190. Select gate 190 and floating gate 184, while being physically and electrically separate, are etched from a single polysilicon layer. Control capacitor 178 may be implemented using a shorted PMOS transistor (e.g., as is tunneling capacitor 176 as described above), shorted NMOS transistor, or in any other suitable or desirable way as those of ordinary skill in the art will now readily appreciate. An exemplary implementation shown in FIGS. 7C and 7D uses a MOS capacitor formed in third n− well 224 to implement control capacitor 178. A portion of floating gate 184 forms one plate of control capacitor 178 and third n− well 224 forms the opposing plate. Floating gate 184 is insulated from third n− well 224 by an insulating layer 258. An n+ diffusion region 260 in third n− well 224 serves as a contact for a control capacitor terminal 200.

Note that it is possible and within the scope of the present invention to modify the device of FIGS. 7A, 7B and 7C so as to merge n− well 220 and n− well 224 into a single n− well 220a (see FIGS. 7E, 7F, 7G and 7H). This modification limits the effectiveness of the control capacitor somewhat but not so much as to remove this modification as an option. It is also possible and within the scope of the present invention to substitute a p+ region 260a for n+ region 260 in either the single or double n− well versions of the present invention (See FIGS. 7G and 7H). It is also possible to substitute a coupled p+/n+ region with a terminal (see e.g., 248/250) for the n+ region 260 or p+ region 260a (not explicitly shown).

Those of ordinary skill in the art will now recognize that the NVM described herein may be configured as single-ended memory or as differential memory, or in other ways in which memory is commonly used without departing from the inventive concepts disclosed herein. It will also now be appreciated by such skilled persons that while the disclosure shows the select transistor in the source leg of the injection transistor, it may alternatively be replaced by any other suitable form of electronic switch and may be placed in either the source leg or the drain leg without significantly affecting the operation of the device. The select transistor or switch is unnecessary in single-bit memories.

While particular embodiments of the present invention have been shown and described, it will now be apparent to those skilled in the art having the benefit of this disclosure that many more modifications than mentioned above are possible without departing from the inventive concepts disclosed herein. Therefore, the appended claims are intended to encompass within their scope all such modifications as are within the true spirit and scope of this invention.

1. A nonvolatile memory (NVM) cell, comprising:
an injection transistor having a source, a floating gate and a drain, the injection transistor having a single layer of conductor out of which the floating gate is formed;
a tunneling capacitor having a first plate and a second plate, the first plate embodying a portion of the floating gate, and a dielectric disposed therebetween; and
a select switch coupled to selectively permit current flow through said injection transistor in response to application of a selection signal thereto.

2. The cell of claim 1, wherein:
the select switch comprises a transistor.

3. The cell of claim 1, wherein:
the select switch comprises a transistor coupled between a power supply and the drain of the injection transistor.

4. The cell of claim 1, wherein:
the select switch comprises a transistor coupled between a power supply and the source of the injection transistor.

5. The cell of claim 3, wherein:
the select switch transistor is a pFET.

6. The cell of claim 3, wherein:
the select switch transistor is an nFET.

7. The cell of claim 4, wherein:
the select switch transistor is a pFET.

8. The cell of claim 4, wherein:
the select switch transistor is an nFET.

9. The cell of claim 2, wherein:
said injection and select switch transistors are formed in a first well of a semiconductor substrate and said tunneling capacitor is formed in a second well of the semiconductor substrate.

10. The cell of claim 9, wherein:
said tunneling capacitor comprises a MOSFET.

11. The cell of claim 10, wherein:
said injection transistor is a pFET.

12. The cell of claim 11, wherein:
said first well is an n− well.

13. The cell of claim 1, further comprising:
a control capacitor having a first plate and a second plate, the first plate embodying a portion of the floating gate, and a dielectric disposed therebetween.

14. The cell of claim 13, wherein:
said control capacitor comprises a MOSFET.

15. A method for altering a number of electrons stored on a floating gate of a memory cell having:
an injection transistor with a source, a floating gate and a drain;
a select switch coupled to selectively permit current flow through the injection transistor in response to application of a selection signal thereto; and
a tunneling capacitor with a first plate and a second plate, the first plate embodying a portion of the floating gate, and a dielectric disposed therebetween; said method comprising:
biasing the second plate of the tunneling capacitor to a first potential;
applying the selection signal to the select switch to close the select switch and applying a first supply voltage to the source of the injection transistor,
wherein said biasing and applying causes electrons to be injected onto the floating gate.

16. The method of claim 15, further comprising:
coupling a second supply voltage to the drain of the injection transistor while said applying is being carried out.

17. The method of claim 15, further comprising:
biasing the second plate of the tunneling capacitor so that electrons are removed from the floating gate by Fowler-Nordheim tunneling.

18. The method of claim 16, further comprising:
biasing the second plate of the tunneling capacitor so that electrons are removed from the floating gate by Fowler-Nordheim tunneling.

19. A memory cell apparatus for altering a number of electrons stored on a floating gate of the memory cell, comprising:
injection transistor means with a source, a floating gate and a drain;
select switch means coupled to selectively permit current flow through the injection transistor in response to application of a selection signal thereto;
tunneling capacitor means with a first plate and a second plate, the first plate embodying a portion of the floating gate, and a dielectric disposed therebetween;
means for biasing the second plate of the tunneling capacitor to a first potential;
means for applying the selection signal to the select switch to close the select switch; and
means for coupling the source of the injection transistor to a first supply voltage,
wherein the means for biasing, applying and coupling cooperate to inject electrons onto the floating gate.

20. The apparatus of claim 19, further comprising:
means for applying a second supply voltage to the drain of the injection transistor while coupling the source of the injection transistor to the first supply voltage,

21. The apparatus of claim 19, further comprising:
means for biasing the second plate of the tunneling capacitor so that electrons are removed from the floating gate by Fowler-Nordheim tunneling.

22. The apparatus of claim 20, further comprising:
means for biasing the second plate of the tunneling capacitor so that electrons are removed from the floating gate by Fowler-Nordheim tunneling.

23. A nonvolatile memory cell, comprising:
a substrate comprising a semiconductor material of a first conductivity type;
a first well of a second conductivity type disposed in the substrate;
a second well of the second conductivity type disposed in the substrate;
a tunneling capacitor having a source region, a drain region and a well contact region electrically coupled together and to a tunneling capacitor terminal and disposed in the first well;
a floating gate formed of a conductive material disposed over at least a portion of the tunneling capacitor and separated from the substrate by a dielectric material;
an injection transistor and a select transistor formed in the second well, the floating gate extending over at least a portion of the injection transistor, the injection transistor including a drain region disposed in the second well and a source region disposed in the second well, the select transistor including a drain region in common with the source region of the injection transistor and a source region, the select transistor also including a select gate having a select gate terminal, the select gate formed of a conductive material and disposed over the region between the source region and drain region of the select transistor, the select gate formed of a same layer of material as the floating gate is formed of and separated from the substrate by a dielectric material; and
a well contact region disposed in the second well and electrically coupled to the source region of the select transistor and to a select transistor source terminal.

24. The nonvolatile memory cell of claim 23, wherein the floating gate is formed of a single layer of polysilicon.

25. The nonvolatile memory cell of claim 24, further comprising:
an overtunneling prevention control circuit coupled to the drain of the injection transistor.

26. A nonvolatile memory cell, comprising:
a p− substrate;
a first and a second n− well disposed in the substrate;
a tunneling capacitor having a p+ source region, a p+ drain region and a n+ well contact region disposed in the first well and electrically coupled together and to a tunneling capacitor terminal;
a floating gate formed of a conductive material disposed over at least a portion of the tunneling capacitor and separated from the substrate by a dielectric material;
an injection transistor and a select transistor formed in the second well, the floating gate extending over at least a portion of the injection transistor, the injection transistor including a p+ drain region disposed in the second well and a p+ source region disposed in the second well, the select transistor including a drain region in common with the p+ source region of the injection transistor and a p+ source region, the select transistor also including a select gate having a select gate terminal, the select gate formed of a conductive material and disposed over the region between the source region and drain region of the select transistor, the select gate separated from the substrate by a dielectric material; and
a n+ well contact region disposed in the second well and electrically coupled to the source region of the select transistor and to a select transistor source terminal.

27. The nonvolatile memory cell of claim 26 wherein the floating gate is formed of a single layer of polysilicon.

28. The nonvolatile memory cell of claim 27, further comprising:
an overtunneling prevention control circuit coupled to the drain of the injection transistor.

29. The nonvolatile memory cell of claim 23, further comprising:
a control capacitor including a third well of the second conductivity type disposed in the substrate; and
a well contact terminal,
wherein the floating gate overlies at least a portion of the third well.

30. The nonvolatile memory cell of claim 29, wherein the floating gate is formed of a single layer of polysilicon separated from the substrate by a thin gate oxide.

31. The nonvolatile memory cell of claim 30, further comprising:
an overtunneling prevention control circuit coupled to the drain of the injection transistor.

32. The nonvolatile memory cell of claim 26, further comprising:
a control capacitor including a third n− well disposed in the substrate; and
an n+ contact region disposed in the third n− well; and
a control capacitor contact terminal electrically coupled to the n+ contact region,
wherein the floating gate overlies at least a portion of the third well.

33. The nonvolatile memory cell of claim 32, wherein the floating gate is formed of a single layer of polysilicon.

34. The nonvolatile memory cell of claim 33, further comprising:
an overtunneling prevention control circuit coupled to the drain of the injection transistor.

35. A nonvolatile memory cell, comprising:
a p− substrate;
a first and a second n− well disposed in the substrate;
a tunneling capacitor disposed in the first well and electrically coupled to a tunneling capacitor terminal;
a floating gate formed of a single layer of a conductive material and disposed over at least a portion of the tunneling capacitor and separated from the substrate by a layer of a dielectric material; and
an injection transistor and a select switch formed in the second well, the floating gate extending over at least a portion of the injection transistor, the injection transistor including a p+ drain region disposed in the second well and a p+ source region disposed in the second well, the select switch having a select terminal and oriented to selectively permit current to flow in the injection transistor.

36. The nonvolatile memory cell of claim 35 wherein the conductive material comprises polysilicon.

37. The nonvolatile memory cell of claim 35, further comprising:
an overtunneling prevention control circuit coupled to the drain of the injection transistor.

38. The nonvolatile memory cell of claim 35, further comprising:
a control capacitor having a first and a second plate, the first plate comprising at least a portion of the floating gate and the second plate comprising a portion of the substrate.

39. The nonvolatile memory cell of claim 38, wherein:
the second plate of the control capacitor comprises at least a portion of a third n− well disposed in the substrate.

40. The nonvolatile memory cell of claim 39, wherein:
the second plate of the control capacitor further comprises a diffusion region disposed within the third n− well.

41. The nonvolatile memory cell of claim 40, wherein:
the diffusion region disposed within the third n− well is an n+ region.

42. The nonvolatile memory cell of claim 40, wherein:
the diffusion region disposed within the third n− well is an p+ region.

43. The nonvolatile memory cell of claim 39, wherein:
the second plate of the control capacitor further comprises a first and a second diffusion region disposed within the third n− well, the first diffusion region being a p+ region and the second diffusion region being an n+ region.

44. The nonvolatile memory cell of claim 38, wherein:
the second plate of the control capacitor comprises at least a portion of the second n− well.

45. The nonvolatile memory cell of claim 44, wherein:
the second plate of the control capacitor further comprises a diffusion region disposed within the second n− well.

46. The nonvolatile memory cell of claim 45, wherein:
the diffusion region disposed within the second n− well is an n+ region.

47. The nonvolatile memory cell of claim 45, wherein:
the diffusion region disposed within the second n− well is an p+ region.

48. The nonvolatile memory cell of claim 44, wherein:
the second plate of the control capacitor further comprises a first and a second diffusion region disposed within the second n− well, the first diffusion region being a p+ region and the second diffusion region being an n+ region.

49. The nonvolatile memory cell of claim 38, further comprising:
an overtunneling prevention control circuit coupled to the drain of the injection transistor.

50. The nonvolatile memory cell of claim 49, wherein said select switch comprises a PFET.

51. The nonvolatile memory cell of claim 50, wherein said PFET includes a drain and a source and said drain shares a p+ diffusion with the source of the injection transistor.

52. A method of operating a nonvolatile memory cell, the nonvolatile memory cell comprising:
a p− substrate;
a first and a second n− well disposed in the substrate;
a tunneling capacitor having a first plate and a second plate, the tunneling capacitor disposed in the first well and electrically coupled to a tunneling capacitor terminal;
a floating gate formed of a single layer of a conductive material and disposed over at least a portion of the tunneling capacitor and separated from the substrate by a layer of a dielectric material; and
an injection transistor and a select switch formed in the second well, the floating gate extending over at least a portion of the injection transistor, the injection transistor including a p+ drain region disposed in the second well and a p+ source region disposed in the second well, the select switch having a select terminal and oriented to selectively permit current to flow in the injection transistor,
the method of operation comprising:
biasing the first plate of the tunneling capacitor to a first potential; and
applying a selection signal to the select switch to close the select switch and thereby couple a first supply voltage to the source of the injection transistor,
wherein said biasing and applying causes electrons to be injected onto the floating gate.

53. A method for altering a number of electrons stored on a floating gate of a memory cell including:
an injection transistor having a source, a floating gate and a drain, the injection transistor having an intrinsic voltage supply range of Vdd (high) to Vss (low), said method comprising:
applying a first voltage signal having a magnitude greater than Vdd to the source of the injection transistor; and
simultaneously applying a second voltage signal having a magnitude less than Vss to the drain of the injection transistor,
wherein, as a result of said applying and said simultaneously applying, electrons are caused to be injected onto the floating gate of the injection transistor.

54. A method for altering a number of electrons stored on a floating gate of a memory cell including:
an injection transistor having a source, a floating gate and a drain, the injection transistor having an intrinsic voltage supply range of Vdd (high) to Vss (low), and
a tunneling capacitor with a first plate and a second plate, the first plate embodying a portion of the floating gate, and a dielectric disposed between the first plate and the second plate; said method comprising:
applying a first voltage signal having a magnitude greater than Vdd to the source of the injection transistor;
simultaneously applying a second voltage signal having a magnitude less than Vss to the drain of the injection transistor; and
biasing the second plate of the tunneling capacitor to a first potential between Vss and Vdd,
wherein, as a result of said applying and simultaneously applying, electrons are caused to be injected onto the floating gate of the injection transistor.

55. A method for altering a number of electrons stored on a floating gate of a memory cell including:
an injection transistor having a source, a floating gate and a drain, the injection transistor having an intrinsic voltage supply range of Vdd (high) to Vss (low),
a tunneling capacitor with a first plate and a second plate, the first plate embodying a portion of the floating gate, and a dielectric disposed between the first plate and the second plate, and
a control capacitor having a third plate and a fourth plate, the third plate embodying a portion of the floating gate, and a dielectric disposed between the third plate and the fourth plate; said method comprising:
applying a first voltage signal having a magnitude greater than Vdd to the source of the injection transistor;
simultaneously applying a second voltage signal having a magnitude less than Vss to the drain of the injection transistor;
biasing the second plate of the tunneling capacitor to a first potential between Vss and Vdd; and
biasing the fourth plate of the control capacitor to a second potential between Vss and Vdd,
wherein, as a result of said applying and simultaneously applying, electrons are caused to be injected onto the floating gate of the injection transistor.

56. The method of claim 55, wherein:
the control capacitor and the injection capacitor are disposed in a same well of a semiconductor substrate and the first potential is substantially equal to said second potential.

57. The method of claim 55, wherein:
the control capacitor and the injection capacitor are disposed in separate wells of a semiconductor substrate.

58. The method of claim 53, wherein:
the memory cell further includes a select switch configured to permit current to flow through the injection transistor only while a select signal is applied to the select switch.

59. The method of claim 54, wherein:
the memory cell further includes a select switch configured to permit current to flow through the injection transistor only while a select signal is applied to the select switch.

60. The method of claim 55, wherein:
the memory cell further includes a select switch configured to permit current to flow through the injection transistor only while a select signal is applied to the select switch.

61. The method of claim 56, wherein:
the memory cell further includes a select switch configured to permit current to flow through the injection transistor only while a select signal is applied to the select switch.

62. The method of claim 57, wherein:
the memory cell further includes a select switch configured to permit current to flow through the injection transistor only while a select signal is applied to the select switch.
